(19) United States
(12) Patent Application Publication
(10) Pub. No.: US 2025/0388122 A1
(43) Pub. Date: Dec. 25, 2025

(54) Battery Monitoring Of Anodes, Cathodes And Separators

(71) Applicant: GM GLOBAL TECHNOLOGY OPERATIONS LLC, Detroit, MI (US)

(72) Inventors: Taylor Reed GARRICK, Bloomfield Hills, MI (US); Samantha BENSON, Royal Oak, MI (US); Erin EFIMOFF, Oak Park, MI (US); Brian J. KOCH, Berkley, MI (US)

(21) Appl. No.: 18/750,498

(22) Filed: Jun. 21, 2024

(51) Int. Cl. B60L 58/15; B60L 58/26; H02J 7/00

(52) U.S. Cl. CPC B60L 58/15; B60L 58/26; H02J 7/00041; H02J 7/00304; H02J 7/00309; H02J 7/007194; H02J 2310/48

(57) ABSTRACT

A vehicle battery monitoring system includes a drive unit including an electric motor to rotate wheels of a vehicle, at least one battery module configured to supply power to the electric motor, the at least one battery module including a cathode, an anode, and a separator between the anode and the cathode, a memory configured to store a cathode equivalent circuit model, an anode equivalent circuit model and a separator equivalent circuit model, and a vehicle control module configured to determine a cathode voltage response of the cathode using the cathode equivalent circuit model, determine an anode voltage response of the anode using the anode equivalent circuit model, determine a separator voltage response of the separator using the separator equivalent circuit model, and modify a charging current supplied to the at least one battery module based on the cathode voltage response, the anode voltage response, and the separator voltage response.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure generally relates to battery monitoring of anodes, cathodes and separators, including monitoring vehicle batteries for lithium plating conditions and overheating.

Lithium ion battery packs may include one or multiple lithium ion battery cells that are electrically connected in parallel or in series, depending upon the needs of the system. Each battery cell includes one or a plurality of lithium ion electrode pairs that are enclosed within a sealed pouch envelope. In some embodiments, each electrode pair includes a negative electrode (e.g., anode) and a positive electrode (e.g., cathode), with a separator arranged therebetween. The separator functions to physically separate and electrically isolate the negative and positive electrodes, while permitting lithium ion transfer.

### SUMMARY

A vehicle battery monitoring system includes a drive unit including at least one electric motor configured to rotate wheels of a vehicle, at least one battery module configured to supply power to the at least one electric motor, the at least one battery module including a cathode, an anode, and a separator between the anode and the cathode, a memory configured to store a cathode equivalent circuit model, an anode equivalent circuit model and a separator equivalent circuit model, and a vehicle control module configured to determine a cathode voltage response of the cathode using the cathode equivalent circuit model, determine an anode voltage response of the anode using the anode equivalent circuit model, determine a separator voltage response of the separator using the separator equivalent circuit model, and modify a charging current supplied to the at least one battery module based on the cathode voltage response, the anode voltage response, and the separator voltage response.

In some examples, the vehicle control module is configured to compare the anode voltage response to a lithium plating voltage threshold indicative of a lithium plating condition likelihood at the anode, and reduce the charging current supplied to the at least one battery module in response to the anode voltage response being less than the lithium plating voltage threshold.

In some examples, the cathode equivalent circuit model is a four parameter (4P) or more equivalent circuit model having one resistor-capacitor pair, the separator equivalent circuit model is a six parameter (6P) or more equivalent circuit model having two resistor-capacitor pairs, and the anode equivalent circuit model is a four parameter (4P) or more equivalent circuit model having one resistor-capacitor pair.

In some examples, the vehicle control module is configured to determine a virtual reference electrode value by calculating a potential drop between a load of the at least one battery module and a voltage at a connection node between the separator and the anode, and modify the charging current supplied to the at least one battery module based on the virtual reference electrode value.

In some examples, the at least one battery module includes multiple battery cells connected in parallel, and a physical reference electrode configured to sense a voltage of at least one of the multiple battery cells, and the vehicle control module is configured to modify the charging current supplied to the at least one battery module based on the voltage sensed by the physical reference electrode.

In some examples, the vehicle control module is configured to calculate an anode heat generation value associated with the anode, calculate a cathode heat generation value associated with the cathode, calculate a separator heat generation value associated with the separator, predict a total heat generation value during operation of the at least one battery module by summing the anode heat generation value, the cathode heat generation value and the separator heat generation value, compare the total heat generation value to a heat threshold indicative of an overheating condition of the at least one battery module, and reduce the charging current supplied to the at least one battery module in response to the total heat generation value being greater than the heat threshold.

In some examples, the vehicle control module is configured to increase a supply of coolant to the at least one battery module to reduce a temperature of the at least one battery module, in response to the total heat generation value being greater than the heat threshold.

In some examples, the vehicle control module is configured to calculate an anode irreversible heat generation value based on the anode equivalent circuit model, calculate a cathode irreversible heat generation value based on the cathode equivalent circuit model, calculate a separator irreversible heat generation value based on the anode equivalent circuit model, and modify the charging current supplied to the at least one battery module based on the anode irreversible heat generation value, the cathode irreversible heat generation value, and the separator irreversible heat generation value.

In some examples, calculating an anode irreversible heat generation value includes multiplying a voltage drop in the anode with the charging current, calculating the separator irreversible heat generation value includes multiplying the charging current with an overpotential value in a liquid phase, and calculating the cathode irreversible heat generation value includes multiplying a voltage drop in the cathode with the charging current.

In some examples, the vehicle control module is configured to calculate an anode reversible heat generation value based on an anode entropy coefficient, calculate a cathode reversible heat generation value based on a cathode entropy coefficient, and modify the charging current supplied to the at least one battery module based on the anode reversible heat generation value and the cathode reversible heat generation value.

In some examples, the anode entropy coefficient is obtained from a first state-of-lithiation dependent look up table associated with a material of the anode, the cathode entropy coefficient is obtained from a second state-of-lithiation dependent look up table associated with a material of the cathode, the anode reversible heat generation value is calculated by multiplying the anode entropy coefficient with a temperature of the at least one battery module and the charging current, and the cathode reversible heat generation value is calculated by multiplying the cathode entropy coefficient with the temperature of the at least one battery module and the charging current.

In some examples, the vehicle control module is configured to apply a Kalman filter to state-of-lithiation calculations associated with the anode entropy coefficient and the cathode entropy coefficient.

In some examples, the vehicle control module is configured to generate a feedforward current prediction value based on at least one of the cathode voltage response, the anode voltage response, or the separator voltage response, and modify at least one charging parameter of the at least one battery module according to the feedforward current prediction value.

In some examples, modifying the at least one charging parameter includes setting a lower charging current value than an instantaneous maximum current limit to avoid a thermal limit of the at least one battery module.

An example method of monitoring a vehicle battery module includes determining, using a cathode equivalent circuit model, a cathode voltage response of a cathode of at least one battery module, the at least one battery module configured to supply power to at least one electric motor of a vehicle, and the at least one battery module including the cathode, an anode, and a separator between the anode and the cathode, determining an anode voltage response of the anode using an anode equivalent circuit model, determining a separator voltage response of the separator using a separator equivalent circuit model, and modifying a charging current supplied to the at least one battery module based on the cathode voltage response, the anode voltage response, and the separator voltage response.

In some examples, the method includes comparing the anode voltage response to a lithium plating voltage threshold indicative of a lithium plating condition likelihood at the anode, and reducing the charging current supplied to the at least one battery module in response to the anode voltage response being less than the lithium plating voltage threshold.

In some examples, the cathode equivalent circuit model is a four parameter (4P) or more equivalent circuit model having one resistor-capacitor pair, the separator equivalent circuit model is a six parameter (6P) or more equivalent circuit model having two resistor-capacitor pairs, and the anode equivalent circuit model is a four parameter (4P) or more equivalent circuit model having one resistor-capacitor pair.

In some examples, the method includes determining a virtual reference electrode value by calculating a potential drop between a load of the at least one battery module and a voltage at a connection node between the separator and the anode, and modifying the charging current supplied to the at least one battery module based on the virtual reference electrode value.

In some examples, the at least one battery module includes multiple battery cells connected in parallel, and a physical reference electrode configured to sense a voltage of at least one of the multiple battery cells, and the method further includes modifying the charging current supplied to the at least one battery module based on the voltage sensed by the physical reference electrode.

In some examples, the method includes calculating an anode heat generation value associated with the anode, calculating a cathode heat generation value associated with the cathode, calculating a separator heat generation value associated with the separator, predicting a total heat generation value during operation of the at least one battery module by summing the anode heat generation value, the cathode heat generation value and the separator heat generation value, comparing the total heat generation value to a heat threshold indicative of an overheating condition of the at least one battery module, and reducing the charging current supplied to the at least one battery module in response to the total heat generation value being greater than the heat threshold.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 is a diagram of an example vehicle including a vehicle battery module.

FIG. 2 is a block diagram depicting an anode, separator and cathode of an example battery module.

FIG. 3 is a line diagram depicting example voltage calculations for the battery module of FIG. 2.

FIG. 4 is a flowchart depicting an example process for determining anode, cathode and separator voltages using equivalent circuit models.

FIG. 5 is a flowchart depicting an example process for modifying charging current to avoid a lithium plating condition of a battery module.

FIG. 6 is a flowchart depicting an example process for calculating anode and cathode heat generation for control of vehicle battery cooling.

FIG. 7A is a line graph illustrating an example entropy trend for a graphite material.

FIG. 7B is a line graph illustrating an example entropy trend for a cathode material.

In the drawings, reference numbers may be reused to identify similar and/or identical elements.

### DETAILED DESCRIPTION

Electric vehicles include battery modules used to power the vehicle, such as supplying power to one or more electric motors. Example battery modules may include one or more lithium ion battery cells that are electrically connected in parallel or in series, depending upon the needs of the system. Each battery cell includes one or more lithium ion electrode pairs, which may be enclosed within a sealed pouch envelope. In some example embodiments, each electrode pair includes a negative electrode (anode) and a positive electrode (cathode), with a separator arranged therebetween. The separator functions to physically separate and electrically isolate the negative and positive electrodes, while permitting lithium ion transfer.

Each battery module may be configured to electrochemically store and release electric power. In some examples, each anode includes a current collector in the form of a copper foil that is coupled to a negative terminal tab, and each cathode includes current collector with an aluminum foil that is coupled to a positive terminal tab. Lithium-ion battery modules (or other suitable battery module types) are capable of being discharged and re-charged over many cycles.

In some examples, a battery monitoring system uses equivalent circuit models representative of each domain in the battery cell (e.g., an anode, a cathode, and a separator) to calculate the battery cell level potential response, as well as determine the voltage response in the anode, cathode, and separator, for control purposes. Additionally, a virtual reference electrode and/or physical reference electrode may be utilized to calibrate towards an anode lithium plating risk during fast charge scenarios.

A domain specific entropy coefficient (e.g., reversible heat) for the anode and cathode, may be coupled with irreversible heat generation in the cathode, anode, and separator liquid phase, to predict heat generation during operation of the battery module. A vehicle control modules may derate or extend the drive cycle as necessary based on the determined heat generation for the battery module.

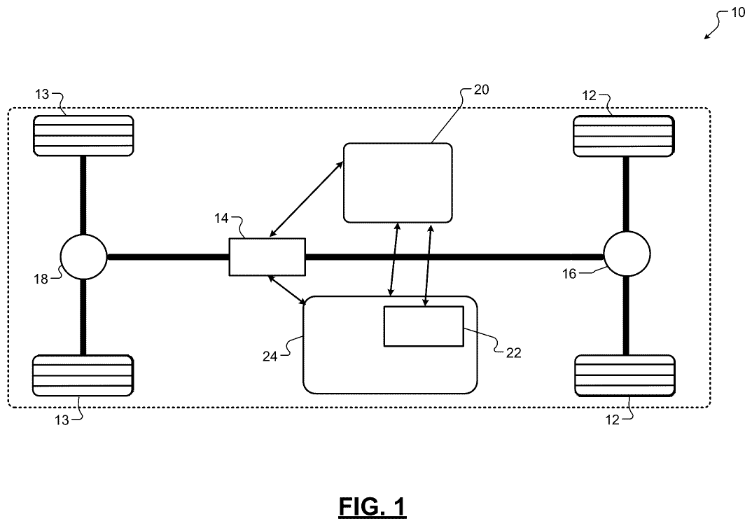

Referring now to FIG. 1, a vehicle 10 includes front wheels 12 and rear wheels 13. In FIG. 1, a drive unit 14 selectively outputs torque to the front wheels 12 and/or the rear wheels 13 via drive lines 16, 18, respectively. The vehicle 10 may include different types of drive units. For example, the vehicle may be an electric vehicle such as a battery electric vehicle (BEV), a hybrid vehicle, or a fuel cell vehicle, a vehicle including an internal combustion engine (ICE), or other type of vehicle.

Some examples of the drive unit 14 may include any suitable electric motor, a power inverter, and a motor controller configured to control power switches within the power inverter to adjust the motor speed and torque during propulsion and/or regeneration. A battery system provides power to or receives power from the electric motor of the drive unit 14 via the power inverter during propulsion or regeneration.

While the vehicle 10 includes one drive unit 14 in FIG. 1, the vehicle 10 may have other configurations. For example, two separate drive units may drive the front wheels 12 and the rear wheels 13, one or more individual drive units may drive individual wheels, etc. As can be appreciated, other vehicle configurations and/or drive units can be used.

The vehicle control module 20 may be configured to control operation of one or more vehicle components, such as the drive unit 14 (e.g., by commanding torque settings of an electric motor of the drive unit 14). The vehicle control module 20 may receive inputs for controlling components of the vehicle, such as signals received from a steering wheel, an acceleration pedal, a brake pedal, etc. The vehicle control module 20 may monitor telematics of the vehicle for safety purposes, such as vehicle speed, vehicle location, vehicle braking and acceleration, etc.

The vehicle control module 20 may receive signals from any suitable components for monitoring one or more aspects of the vehicle, including one or more vehicle sensors (such as cameras, microphones, pressure sensors, steering wheel position sensors, braking sensors, location sensors such as global positioning system (GPS) antennas, wheel height and/or position sensors, accelerometers, etc.). Some sensors may be configured to monitor current motion of the vehicle, acceleration of the vehicle, braking of the vehicle, current steering direction of the vehicle, current height and/or position of one or more wheels, etc.

The vehicle includes one or more battery modules 24. The battery modules 24 may be configured to supply power to the drive unit 14 to move the vehicle, such as supplying electric power to an electric motor of the vehicle 10. The battery modules 24 may be charged by an external power source, such as an electric utility grid, dedicated electric vehicle chargers, etc.

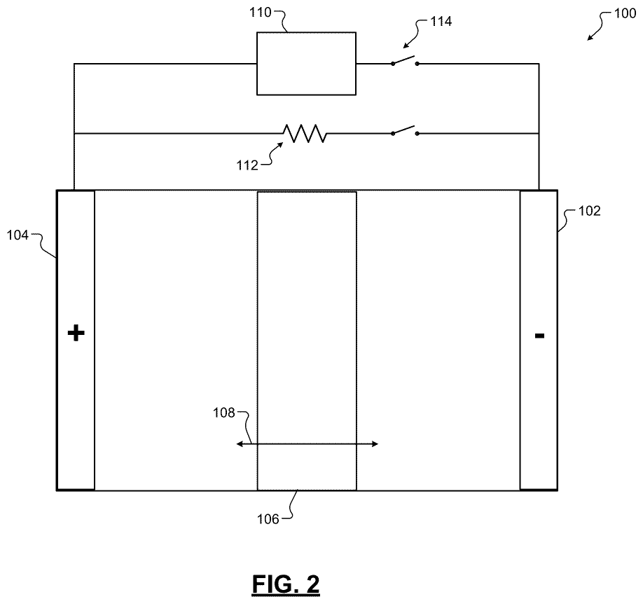

The battery modules 24 may include one or more battery cells, which may each include an anode, a cathode, and a separator, as described further below (e.g., with reference to FIG. 2). The vehicle control module 20 may use equivalent circuit models for the anode, the cathode and the separator, to determine voltage responses for the anode, the cathode, the separator, and the cell overall, to execute control operations associated with the battery modules 24.

For example, the vehicle control module may be configured to reduce a charging current if an anode voltage reduces below a lithium plating voltage threshold to avoid a lithium plating condition, may reduce a charging current or increase a supply of coolant to avoid a battery overheating condition, etc. One or more sensors 22 may be in communication with the vehicle control module 20, where the sensors are configured to sense parameters of the battery modules 24 (such as sensing voltages at different locations within the battery modules 24).

The vehicle control module 20 may communicate with another device via a wireless communication interface, which may include one or more wireless antennas for transmitting and/or receiving wireless communication signals. For example, the wireless communication interface may communicate via any suitable wireless communication protocols, including but not limited to vehicle-to-everything (V2X) communication, Wi-Fi communication, wireless area network (WAN) communication, cellular communication, personal area network (PAN) communication, short-range wireless communication (e.g., Bluetooth), etc. The wireless communication interface may communicate with a remote computing device over one or more wireless and/or wired networks. Regarding the vehicle-to-vehicle (V2X) communication, the vehicle 10 may include one or more V2X transceivers (e.g., V2X signal transmission and/or reception antennas).

FIG. 2 is a block diagram depicting an anode 102, separator 106 and cathode 104 of an example battery module 100. For example, the separator 106 may include a permeable membrane placed between the anode 102 and cathode 104 of the battery module 100.

The separator 106 may operate to keep material of the anode 102 and the cathode 104 apart, to inhibit or prevent electrical short circuits while also allowing the transport of ionic charge carriers that are used to close a circuit during the passage of current in an electrochemical cell. For example, ion transport 108 may occur from the anode 102 to the cathode 104 or vice versa, through the separator 106. This may allow the battery module 100 to either be charged via a charger 110, or to discharge power to a load 112, such as via selective operation of switches 114.

Separators may be used in liquid electrolyte batteries, solid state batteries, polymer electrolyte batteries, etc. The separator 106 may include a polymeric membrane forming a microporous layer. The separator 106 may be chemically and electrochemically stable with regard to the electrolyte and electrode materials, and mechanically strong enough to withstand high tension during battery construction. The separator 106 structure and properties considerably affect the performance of the battery module 100, including the energy and power densities, cycle life, and safety of the battery module 100.

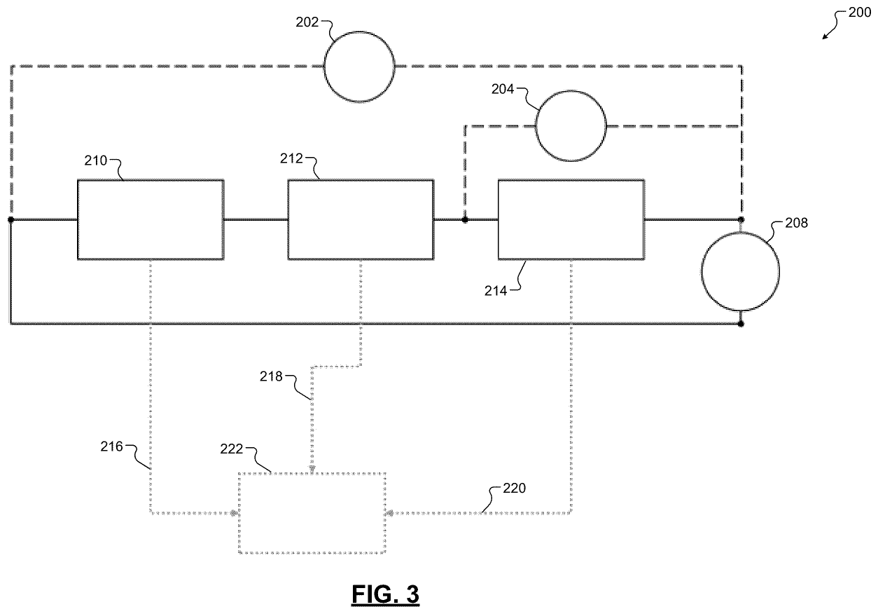

FIG. 3 is a line diagram depicting example voltage calculations for a battery module 200. For example, FIG. 3 illustrates a cell voltage 202, an anode voltage 204, and a load 208 of the battery module 200. Three equivalent circuit models may be used to determine voltage responses for different components of the battery module 200.

For example, a cathode equivalent circuit model 210 may be used to determine a voltage response of the cathode, a separator equivalent circuit model 212 may be used to determine a voltage response of the separator, and an anode equivalent circuit model 214 may be used to determine a voltage response of the anode.

Each equivalent circuit model may have a specified number of parameters. For example, the cathode equivalent circuit model 210 may be a four parameter (4P) model, where the four parameters may include a voltage, a resistor and a resistor-capacitor pair. The separator equivalent circuit model 212 may be a 4P model, and the anode equivalent circuit model may be a six parameter (6P) model, where two resistor-capacitor pairs are included. In other examples, any suitable number of parameter models may be used, such as an 8P model, a 10P model, etc., which may represent any suitable number of equivalent circuit elements.

As shown in FIG. 3, multiple heat generation values may be calculated, which may be specific to different components. For example, the system may calculate a cathode heat generation value 216, a separator heat generation value 218, and an anode heat generation value 220. In some examples, the cathode heat generation value 216 may be calculated according to the following equation:

$${Q}_{Cathode} = I ( {V}_{Cathode} - {OCV}_{Cathode} ) + {TI ( \frac{dU}{dT} )}_{Cathode}$$

In some examples, the anode heat generation value 220 may be calculated according to the following equation:

$${Q}_{Anode} = I ( {V}_{Anode} — {OCV}_{Anode} ) + {TI ( \frac{dU}{dT} )}_{Anode}$$

In some examples, the separator heat generation value 218 may be calculated according to the following equation:

$${Q}_{Separator} = I ( {η}_{Separator} )$$

The cathode heat generation value 216, the separator heat generation value 218, and the anode heat generation value 220 may be combined (e.g., summed) to determine a total heat generation value 222 for the battery module 200.

In some examples, current for each component may be determined based on a state-of-lithiation (SOL) associated with a material of the component. The SOL may be implemented in a lookup table, etc. For example, the cathode current may be determined according to the following equation:

$${( \frac{dU}{dT} )}_{Cathode} = f ( SOL )$$

As an example, the cathode current may be determined according to the following equation:

$${( \frac{dU}{dT} )}_{Anode} = f ( SOL )$$

As used above, I may represent current in amps, V_{cathode} is a measured voltage, and OCV is an equilibrium voltage (e.g., open circuit voltage). dU/dT represents a change in the equilibrium based on a change in temperature (e.g., an entropy coefficient). The entropy of the system may be a function of how much lithium is in the cathode, for example. dU/dT values may be specific to materials used for the cathode and anode respectively, based on amounts of lithiation (such as a Faraday constant times a number of electrons). ηₛₑₚₐᵣₐₜₒᵣ may represent an overpotential in the separator, such as how much voltage loss or power loss occurs in the separator when there is a charge.

In some examples, equivalent circuit models may be used to capture voltage responses in a cathode of the battery module, an anode of the battery module, and a separator of the battery module. For example, the cathode voltage response may be captured by a four parameter (4P) equivalent circuit model (e.g., a voltage parameter, a resistance parameter, and a resistor-capacitor pair), the separator liquid phase overpotential may be captured by a 4P equivalent circuit model, and the anode voltage response may be captured by a 6P (e.g., including two resistor-capacitor pairs) or higher equivalent circuit model.

A virtual reference electrode may be utilized by calculating the potential drop between a load of the battery module, and the voltage at the separator/anode connection. In some examples, a battery module may include a grouping of battery cells, such as 2 or 3 (or more) cells connected in parallel. The system may assume that the voltage response of each cell connected in parallel will be the same, allowing for virtual prediction of the cell response for the cell grouping. Each cell grouping may have a voltage sensor, a temperature sensor, etc. Some cells may have a physical reference electrode, while others may not.

Heat generation from each domain (e.g., anode, cathode and separator) may be summed to predict the overall heat generation of the battery module during operation, and may be utilized for feedforward calculation and control based on the local and bulk thermal mass. Feedforward calculation may be used, for example, to avoid hitting a thermal limit by quantifying various heat transfer terms in the system, such as a chiller, coolant flow, etc. Feedforward control may be used for a maximum temperature limit. The feedforward control may indicate that a lower power or lower current should be used compared to an instantaneous maximum limit. Integrating the feedforward current prediction may provide an estimate of the total energy transferred to the system.

In some examples, irreversible heat generation in the cathode may be captured by the multiplication of the voltage drop in the cathode and the current (e.g., charging or discharging current of the battery module). Irreversible heat generation in the separator may be captured by the overpotential in the liquid phase multiplied by the current, and irreversible heat generation in the anode may be captured by the multiplication of the voltage drop in the cathode and the current.

Reversible heat generation is considered by the vehicle control module, such as by use of entropy coefficients for the cathode and the anode. The entropy coefficient for the cathode may be based on a state-of-lithiation dependent lookup table (e.g., specific to a material of the cathode), and the reversible heat generation for the cathode may be calculated by the product of the cathode entropy coefficient, a temperature of the battery module, and a current of the battery module. The entropy coefficient for the anode may be based on a state-of-lithiation dependent lookup table (e.g., specific to a material of the anode), and the reversible heat generation is calculated by the product of the entropy coefficient, temperature, and current. In some examples, feedforward control may consider reversible heat generation to modify a time to reach a thermal limit at any given maximum current, by adding or removing heat to or from the system.

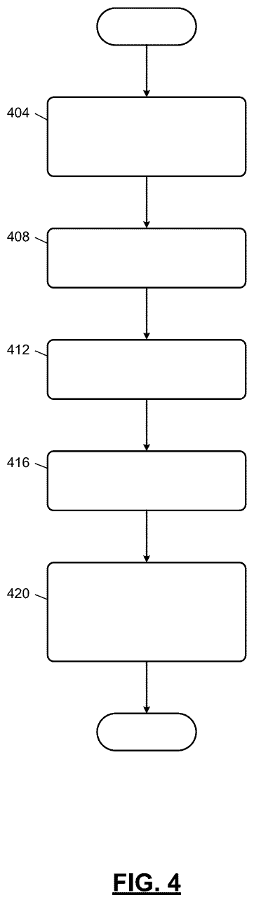

FIG. 4 is a flowchart depicting an example process for determining anode, cathode and separator voltages using equivalent circuit models. The process may be performed by, for example, the vehicle control module 20 of FIG. 1. At 404, the process begins by obtaining equivalent circuit models for an anode of a battery module (such as the battery module 24 of FIG. 1), a cathode of the battery module, and a separator of the battery module. For example, the vehicle control module 20 may include a memory configured to store equivalent circuit models for each of the anode, the cathode and the separator of the battery module 24.

At 408, the vehicle control module is configured to determine a cathode voltage response of the cathode using the cathode equivalent circuit model. The vehicle control module is configured to determine an anode voltage response of the anode using the anode equivalent circuit model, at 412.

At 416, the vehicle control module is configured to determine a separator voltage response of the separator using the separator equivalent circuit model. The process continues at 420 by modifying a charging current supplied to the at least one battery module based on the cathode voltage response, the anode voltage response, and the separator voltage response.

In some examples, the anode voltage response, the cathode voltage response, and the separator voltage response may be combined (e.g., summed) to generate an overall voltage response of the battery module. The voltage responses, individually or in combination, may be used to perform control operations of the battery module, such as determining a state of charge of the battery module, predicting future (or current) lithium plating or overheating conditions of the battery module, etc.

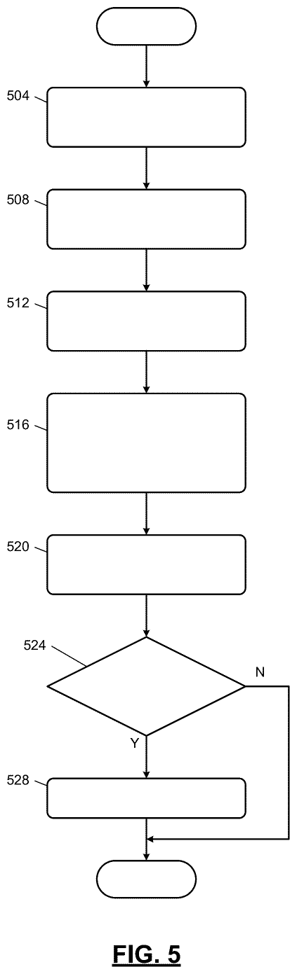

FIG. 5 is a flowchart depicting an example process for modifying charging current to avoid a lithium plating condition of a battery module. The process may be performed by, for example, the vehicle control module 20 of FIG. 1. At 504, the process begins by determining a cathode voltage response for a cathode of a battery module (e.g., the battery module 24 of FIG. 1), using an equivalent circuit model.

The vehicle control module is configured to determine an anode voltage response of the anode using the anode equivalent circuit model, at 508, and to determine a separator voltage response of the separator using the separator equivalent circuit model, at 512. These steps may be similar to steps in the example process of FIG. 5.

At 516, the vehicle control module is configured to calculate a virtual reference electrode based on a potential drop between a battery load and a voltage at a connection of the anode and separator. Control then compares the anode voltage response to a lithium plating voltage threshold at 520.

For example, control may determine whether a voltage response of the anode is below a lithium plating voltage threshold indicative of a likelihood or risk of a lithium plating condition occurring at the battery module (e.g., on the anode of the battery module). If the anode voltage is less than the lithium plating voltage threshold at 524, control decreases a charging current supplied to the battery module. Reducing the charging current may inhibit or prevent the lithium plating condition from occurring, because the anode voltage may rise in response to a reduction in charging current. In some examples, a limit may be set at OV versus Li+/Li metal, a positive offset (e.g., 10 mV versus Li+/Li metal), etc., which may depend on how conservative or aggressive a desired charge control should be.

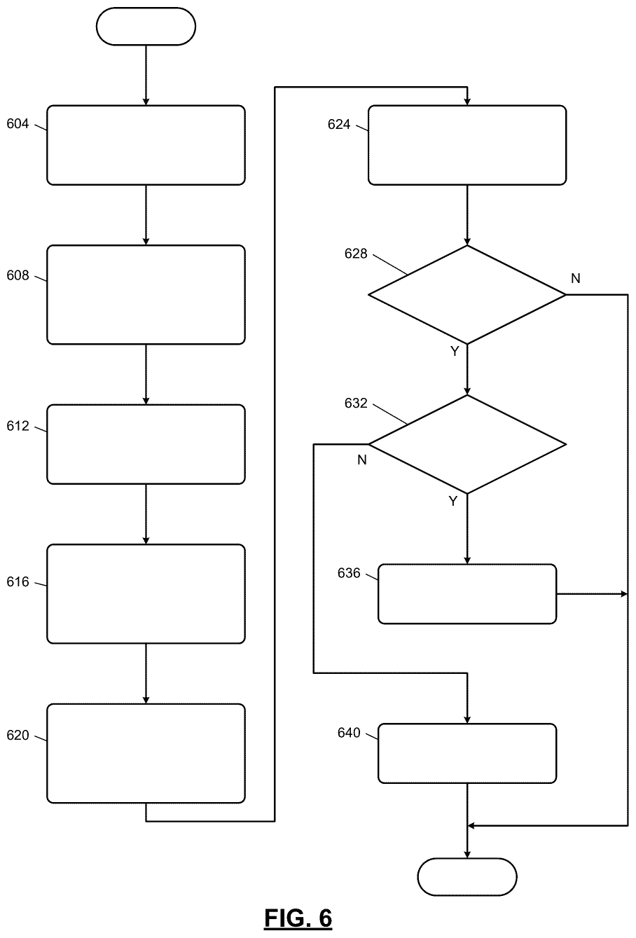

FIG. 6 is a flowchart depicting an example process for calculating anode and cathode heat generation for control of vehicle battery cooling. The process may be performed by, for example, the vehicle control module 20 of FIG. 1. At 604, the process begins by calculating an anode irreversible heat generation in the battery module, such as by multiplying an anode voltage drop with a current (e.g., a current though the anode).

At 608, the vehicle control module is configured to calculate a separator irreversible heat generation value, which may be based on multiplying a liquid phase overpotential of the separator with a current (e.g., a current through the separator, a current of the battery module, etc.). The process continues at 612 by calculating a cathode irreversible heat generation based on, for example, multiplying a cathode voltage drop with a current (e.g., a current through the cathode).

At 616, the vehicle control module is configured to calculate an anode reversible heat generation using an anode entropy coefficient. The anode entropy coefficient may be determined by a state-of-lithiation (SOL) look up table, which may correspond to a material of the anode (such as graphite, etc.).

The vehicle control module is configured to calculate a cathode reversible heat generation at 620, using a cathode entropy coefficient. The cathode entropy coefficient may be determined by a state-of-lithiation (SOL) look up table, which may correspond to a material of the cathode (such as an NMC-811 cathode material, etc.).

At 624, control is configured to compare a total heat generation value (which may be based on a combination of separately calculated heat generation values for the anode, cathode and separator), to a heat threshold indicative of an overheating condition. For example, a heat threshold may be set (such as via experimentation, modeling, etc.), which is indicative of a risk or likelihood of an overheating condition of the battery module (e.g., a thermal runaway condition of the battery module).

If the total heat generation value is greater than the heat threshold at 628, control proceeds to 632 to determine a current setting for cooling the battery or avoiding an overheating condition. For example, the vehicle control module may determine at 632 whether a heat reduction approach is set to increasing a flow of coolant. If so, control proceeds to 636 to increase a coolant supplied to the battery module to cool the battery module and avoid the overheating condition. Additionally, or alternatively, control may reduce a charging current supplied to the battery module at 640 (or reduce a current flowing out of the battery module), to cool the battery and avoid an overheating condition.

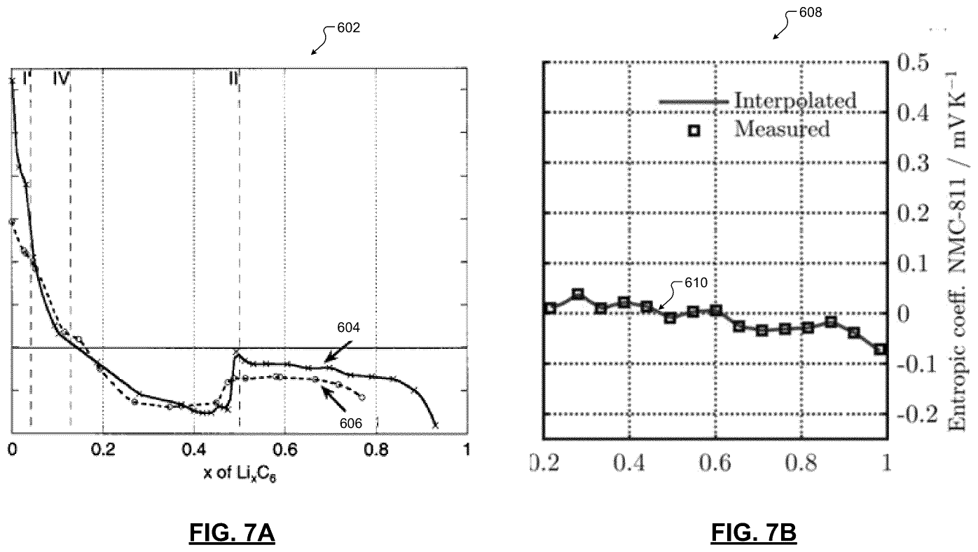

FIG. 7A is a line graph illustrating an example entropy trend 602 for a graphite material. FIG. 7A illustrates a natural graphite entropy coefficient 604 with respect to a state-of-lithiation. The natural graphite material may be used for an anode, for example. FIG. 7A also illustrates an MCMB entropy coefficient 606 for mesocarbon microbeads at 2800 degrees Celsius.

FIG. 7B is a line graph illustrating an example entropy trend 608 for a cathode material. FIG. 7B illustrates a cathode material entropy coefficient 610 with respect to a state-of-lithiation. The cathode material may be any suitable material for use as a cathode, such as an NMC-811 cathode material.

Some example embodiments described herein may utilize an equivalent circuit model to capture the cathode, anode, and separator voltage response, such as in a vehicle battery module. However, the example embodiments are not limited to vehicles, and may be used to analyze other battery types having anodes, cathodes and separators, in implementations other than vehicles.

In some examples, the cathode voltage response may be captured by a 4P (or higher order) equivalent circuit model, the separator liquid phase overpotential may be captured by a 4P (or higher order) equivalent circuit model, and the anode voltage response may be captured by a 6P or higher equivalent circuit model. A virtual reference electrode may be utilized by calculating the potential drop between the battery load and the voltage at the separator/anode connection of the battery.

A vehicle control module may be configured to calculate the heat generation from each domain (e.g., anode, cathode and separator), and sum the individual heat generation values to predict total heat generation during operation of the battery module. This may be utilized for feedforward calculation and control of the battery module, based on the local and bulk thermal mass.

Some example embodiments may calculate irreversible heat generation from the equivalent circuit model in each domain (e.g., anode, cathode and separator). For example, irreversible heat generation in the cathode may be captured by the multiplication of the voltage drop in the cathode and the current, irreversible heat generation in the separator may be captured by the overpotential in the liquid phase multiplied by the current, and irreversible heat generation in the anode may be captured by the multiplication of the voltage drop in the anode and the current.

Some example embodiments may calculate reversible heat generation in the anode and cathode, using an anode entropy coefficient and a cathode entropy coefficient. For example, the entropy coefficient for the cathode may be based on a state-of-lithiation dependent lookup table, and the reversible heat generation for the cathode may be calculated by the product of the cathode entropy coefficient, temperature, and current. The entropy coefficient for the anode may be based on a state-of-lithiation dependent lookup table, and the reversible heat generation for the anode may be calculated by the product of the entropy coefficient, temperature, and current. In some examples, a Kalman filter may be used to aid state estimation for state-of-lithiation calculations, for internal variable tracking.

Various example embodiments may provide one or more advantages for battery module monitoring, such as explicit calculation of the battery cell potential, explicit calculation of the cathode potential, explicit calculation of the anode potential, and explicit calculation of the separator overpotential in the liquid phase. These values may be used for control operations of the battery module based on the cathode, anode, and cell potential.

Irreversible heat generation calculation in each domain may be used for a feed forward determination of the heat generation. Reversible heat generation calculation in the anode and cathode may be used, such as for low current use cases (e.g., limited charging due to a cooling failure, limited charging due to a coolant pump failure, or propulsion derating due to thermal limits, etc.).

In some examples, the anode potential may be used for determination of a lithium plating risk, such as during a fast ECM strategy in vehicle. Overall cell response may be updated as the battery module ages, based on individual changes in voltage responses of the anode, cathode and separator, for example.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A vehicle battery monitoring system comprising:
a drive unit including at least one electric motor configured to rotate wheels of a vehicle;
at least one battery module configured to supply power to the at least one electric motor, the at least one battery module including at least one battery cell, the at least one battery cell including at least a cathode, an anode, and a separator between the anode and the cathode;
a memory configured to store a cathode equivalent circuit model, an anode equivalent circuit model and a separator equivalent circuit model; and
a vehicle control module configured to:
determine a cathode voltage response of the cathode using the cathode equivalent circuit model;
determine an anode voltage response of the anode using the anode equivalent circuit model;
determine a separator voltage response of the separator using the separator equivalent circuit model; and
modify a charging current supplied to the at least one battery module based on the cathode voltage response, the anode voltage response, and the separator voltage response.

2. The vehicle battery monitoring system of claim 1, wherein the vehicle control module is configured to:
compare the anode voltage response to a lithium plating voltage threshold indicative of a lithium plating condition likelihood at the anode; and
reduce the charging current supplied to the at least one battery module in response to the anode voltage response being less than the lithium plating voltage threshold.

3. The vehicle battery monitoring system of claim 1, wherein:
the cathode equivalent circuit model is a four parameter (4P) or more equivalent circuit model having one resistor-capacitor pair;
the separator equivalent circuit model is a six parameter (6P) or more equivalent circuit model having two resistor-capacitor pairs; and
the anode equivalent circuit model is a four parameter (4P) or more equivalent circuit model having one resistor-capacitor pair.

4. The vehicle battery monitoring system of claim 1, wherein the vehicle control module is configured to:
determine a virtual reference electrode value by calculating a potential drop between a load of the at least one battery module and a voltage at a connection node between the separator and the anode; and
modify the charging current supplied to the at least one battery module based on the virtual reference electrode value.

5. The vehicle battery monitoring system of claim 1, wherein:
the at least one battery module includes multiple battery cells connected in parallel, and a physical reference electrode configured to sense a voltage of at least one of the multiple battery cells; and
the vehicle control module is configured to modify the charging current supplied to the at least one battery module based on the voltage sensed by the physical reference electrode.

6. The vehicle battery monitoring system of claim 1, wherein the vehicle control module is configured to:
calculate an anode heat generation value associated with the anode;
calculate a cathode heat generation value associated with the cathode;
calculate a separator heat generation value associated with the separator;
predict a total heat generation value during operation of the at least one battery module by summing the anode heat generation value, the cathode heat generation value and the separator heat generation value;
compare the total heat generation value to a heat threshold indicative of an overheating condition of the at least one battery module; and
reduce the charging current supplied to the at least one battery module in response to the total heat generation value being greater than the heat threshold.

7. The vehicle battery monitoring system of claim 6, wherein the vehicle control module is configured to increase a supply of coolant to the at least one battery module to reduce a temperature of the at least one battery module, in response to the total heat generation value being greater than the heat threshold.

8. The vehicle battery monitoring system of claim 1, wherein the vehicle control module is configured to:
calculate an anode irreversible heat generation value based on the anode equivalent circuit model;
calculate a cathode irreversible heat generation value based on the cathode equivalent circuit model;
calculate a separator irreversible heat generation value based on the anode equivalent circuit model; and
modify the charging current supplied to the at least one battery module based on the anode irreversible heat generation value, the cathode irreversible heat generation value, and the separator irreversible heat generation value.

9. The vehicle battery monitoring system of claim 8, wherein:
calculating an anode irreversible heat generation value includes multiplying a voltage drop in the anode with the charging current;
calculating the separator irreversible heat generation value includes multiplying the charging current with an overpotential value in a liquid phase; and
calculating the cathode irreversible heat generation value includes multiplying a voltage drop in the cathode with the charging current.

10. The vehicle battery monitoring system of claim 8, wherein the vehicle control module is configured to:
calculate an anode reversible heat generation value based on an anode entropy coefficient;
calculate a cathode reversible heat generation value based on a cathode entropy coefficient; and
modify the charging current supplied to the at least one battery module based on the anode reversible heat generation value and the cathode reversible heat generation value.

11. The vehicle battery monitoring system of claim 10, wherein:
the anode entropy coefficient is obtained from a first state-of-lithiation dependent look up table associated with a material of the anode;
the cathode entropy coefficient is obtained from a second state-of-lithiation dependent look up table associated with a material of the cathode;
the anode reversible heat generation value is calculated by multiplying the anode entropy coefficient with a temperature of the at least one battery module and the charging current; and
the cathode reversible heat generation value is calculated by multiplying the cathode entropy coefficient with the temperature of the at least one battery module and the charging current.

12. The vehicle battery monitoring system of claim 11, wherein the vehicle control module is configured to apply a Kalman filter to state-of-lithiation calculations associated with the anode entropy coefficient and the cathode entropy coefficient.

13. The vehicle battery monitoring system of claim 1, wherein the vehicle control module is configured to:
generate a feedforward current prediction value based on at least one of the cathode voltage response, the anode voltage response, or the separator voltage response; and
modify at least one charging parameter of the at least one battery module according to the feedforward current prediction value.

14. The vehicle battery monitoring system of claim 1, wherein modifying the at least one charging parameter includes setting a lower charging current value than an instantaneous maximum current limit to avoid a thermal limit of the at least one battery module.

15. A method of monitoring a vehicle battery module, the method comprising:
determining, using a cathode equivalent circuit model, a cathode voltage response of a cathode of at least one battery cell of at least one battery module, the at least one battery module configured to supply power to at least one electric motor of a vehicle, and the at least one battery cell including the cathode, an anode, and a separator between the anode and the cathode;
determining an anode voltage response of the anode using an anode equivalent circuit model;
determining a separator voltage response of the separator using a separator equivalent circuit model; and
modifying a charging current supplied to the at least one battery module based on the cathode voltage response, the anode voltage response, and the separator voltage response.

16. The method of claim 15, further comprising:
comparing the anode voltage response to a lithium plating voltage threshold indicative of a lithium plating condition likelihood at the anode; and
reducing the charging current supplied to the at least one battery module in response to the anode voltage response being less than the lithium plating voltage threshold.

17. The method of claim 15, wherein:
the cathode equivalent circuit model is a four parameter (4P) or more equivalent circuit model having one resistor-capacitor pair;
the separator equivalent circuit model is a six parameter (6P) or more equivalent circuit model having two resistor-capacitor pairs; and
the anode equivalent circuit model is a four parameter (4P) or more equivalent circuit model having one resistor-capacitor pair.

18. The method of claim 15, further comprising:
determining a virtual reference electrode value by calculating a potential drop between a load of the at least one battery module and a voltage at a connection node between the separator and the anode; and
modifying the charging current supplied to the at least one battery module based on the virtual reference electrode value.

19. The method of claim 15, wherein:
the at least one battery module includes multiple battery cells connected in parallel, and a physical reference electrode configured to sense a voltage of at least one of the multiple battery cells; and
the method further includes modifying the charging current supplied to the at least one battery module based on the voltage sensed by the physical reference electrode.

20. The method of claim 15, further comprising:
calculating an anode heat generation value associated with the anode;
calculating a cathode heat generation value associated with the cathode;
calculating a separator heat generation value associated with the separator;
predicting a total heat generation value during operation of the at least one battery module by summing the anode heat generation value, the cathode heat generation value and the separator heat generation value;
comparing the total heat generation value to a heat threshold indicative of an overheating condition of the at least one battery module; and
reducing the charging current supplied to the at least one battery module in response to the total heat generation value being greater than the heat threshold.
